(19) United States
(12) Patent Application Publication
(10) Pub. No.: US 2016/0172027 A1
(43) Pub. Date: Jun. 16, 2016

(54) Polymer Memory

(71) Applicant: CONVERSANT INTELLECTUAL PROPERTY MANAGEMENT INC., Ottawa (CA)

(72) Inventors: Ehsan Tahmasebian, Winnipeg (CA); Hyoung Seub Rhie, Ottawa (CA); Peter Gillingham, Ottawa (CA)

(73) Assignee: CONVERSANT INTELLECTUAL PROPERTY MANAGEMENT INC., Ottawa (CA)

(21) Appl. No.: 14/571,949

(22) Filed: Dec. 16, 2014

(51) Int. Cl. G11C 13/00; H01L 51/00; H01L 51/10

(52) U.S. Cl. CPC G11C 13/0016; G11C 13/003; H01L 51/102; H01L 51/0002

(57) ABSTRACT

A integrated circuit device with a polymer memory array includes active circuits formed in lower layers of a multi-level interconnect structure and a semiconductor substrate and also includes an array of polymer memory cells formed in an upper interconnect level having a plurality of cell node electrodes and source line electrodes for the polymer memory array, each polymer memory cell including a passive layer having at least one conductivity-facilitating compound that is formed on top and sidewall surfaces of a source line electrode, and an active layer having an impedance state that can change that is formed on top and sidewall surfaces of an adjacent cell node electrode with sufficient thickness to make direct physical contact with the passive layer.

### BACKGROUND OF THE INVENTION

1. Field of the Invention

The present invention is directed in general to integrated circuit devices and methods for manufacturing same. In one aspect, the present invention relates to a polymer junction formed in a semiconductor device.

2. Description of the Related Art

Though microchips made with silicon-based process technology continue to provide high-speed and high-density memory devices, there are performance and density limitations relating to fabrication complexity, expense, and scaling limitations. To address such limitations, resistive memory technology is being explored which uses electrically conducting polymers to store data. Rather than encoding data values with the amount of charge stored on a capacitor in a silicon-based memory cell, a polymer memory cell stores information by controlling the electrical resistance of one or more polymer layers that are sandwiched between two electrodes. Application of an electric field to a cell lowers the polymer's resistance, thus increasing its ability to conduct current, and the polymer maintains its state until a field of opposite polarity is applied to raise its resistance back to its original level. The different conductivity states represent bits of information stored in the polymer memory cell.

One approach for fabricating polymer memory cells is based on the reduction/oxidation (“redox”) of a solid-state polymer junction by using compensation doping to induce bulk conductivity changes in a polymer layer via field-induced ion relocation across solid-state junctions. To illustrate an example redox-based approach, reference is made to FIG. 1 which shows a simplified schematic diagram of a polymer memory structure 1 in which a voltage source 7 is connected to a memory cell 8 formed with two metal electrodes 2, 6 which sandwich a multi-layered structure of a compensatively-doped conjugated polymer layer 3 (e.g., polythiophene (PT)) electrodeposited in the presence of dodecyl sulfate (DS−)), an interfacial conjugated polymer layer 4 (e.g., polypyrrole (PPy)) deposited in the presence of dodecyl benzene sulfonate (DBS−)), and an undoped metal oxide layer 5 (e.g., electrochemically deposited WO₃). In this memory cell 8, the junction consists of the compensatively-doped, neutral conjugated polymer 3-4 and the undoped metal oxide 5 in a net low conductivity state. Upon the application of a sufficiently large field by the voltage supply 7, mobile cations (Li⁺) relocate into the metal oxide layer 5, resulting in an n-doped metal oxide layer 5 and p-doped conjugated polymer 3-4 in a net high conductivity state. Relaxation to the low conductivity state in the absence of an external field is then dictated by the thermodynamics of the system defined by the initial electrochemical potential of the system when fabricated. By creating a well-defined barrier to ion drift that remains electronically conducting, the polymer memory cell 8 provides a mechanism to create stable states that can control volatility and provide a means to optimize memory devices for various applications, such as static or dynamic memory devices.

To understand the operation of the polymer memory structure 1 shown in FIG. 1, reference is now made to FIG. 2 which illustrates a current-voltage characteristics curve 2 for a polymer memory structure 1 in which a diode-like characteristic is observed as voltage is increased from 0V. To represent the polymer memory cell 8, an electrical symbol consisting of a diode and a resistor is shown with the diode oriented in the direction of positive current flow I and the resistor is located at the WO₃ side of the junction. In operation, when the voltage is increased to a write potential V_{WRITE} (as indicated along the IV curve 10), the Li⁺ ions are displaced to move from the PT(Li⁺ DS⁻) layer 3 to the WO₃ layer 5, resulting in a lower resistance state and higher current at the junction. This state persists and can be detected in a read operation by applying a read voltage V_{READ} that is lower than V_{WRITE} and insufficient to displace the Li⁺ ions. If the junction had been written with a write potential V_{WRITE}, a current I₁ will be observed upon application of the read voltage V_{READ}, and the read data will be interpreted as a logical ‘1’ value. However, if the junction had not been written, a current I₀ less than I₁ will be observed upon application of the read voltage V_{READ}, and the read data will be interpreted as a logical ‘0’ value. Over a period of time, the read current through a cell that had been written with V_{WRITE} will gradually fall to I₀, so the polymer memory cell 8 must be periodically refreshed by reading the data from the cell and then writing the data back to the cell. For the cell materials discussed, V_{WRITE} may be in the range of 3-5V, and V_{READ} may be around 1V.

In addition to the operational requirements for periodically refreshing stored cell data, it will be appreciated that there are other challenges with fabricating the sandwiched polymer memory cell structure 1 by forming the layers 3-5 in sequence. For example, to account for the fact that the PPy layer 4 is more easily oxidized, the electrochemical potential is set to 0 V vs. Ag/AgCl in the presence of Li⁺-containing electrolyte, thereby resulting in a compensatively doped PT(DS⁻Li⁺) layer 3, doped PPy(DBS⁻) layer 4, and undoped WO₃ layer 5. But as Li⁺ passes through the doped PPy(DBS⁻) layer 4, a space charge region is formed, resulting in an increase in energy of the polymer memory cell which amounts to a barrier to ion transport. In this case, the junction of the WO₃ layer 5 and PT layer 3 with the PPy barrier layer 4 is made by sandwiching a WO₃-coated indium tin oxide electrode 5-6 and PT-PPy-coated indium tin oxide electrode 2-4 together in a dry state. While it is possible to create a junction by physically sandwiching the WO₃ and PT-PPy coated electrodes together, this technique is not suited to fabrication of practical memory devices in conventional semiconductor processes. For example, it is difficult to integrate new materials, such as polythiophene and polypyrrole, into the process flow of conventional semiconductor processes due to contamination risks to other process steps by the new materials and the effect of subsequent high temperature steps on the new materials. In addition, electrochemical deposition of PT-PPy at positive potentials is not compatible with CMOS metals, such as copper, as it will oxidize them. By replacing the PT layer 3 and PPy barrier layer 4 with a conductive polymer—such as PEDOT:PSS or Poly(3,4-ethylenedioxythiophene) Polystyrene sulfonate—that can be deposited electrophoretically at negative potential on the CMOS metals, such as copper, this issue can solved. In this structure, after the electrochemical potential is being set to 0 V vs. Ag/AgCl in the presence of Li⁺-containing electrolyte, the system will consist of undoped WO₃ in low conductivity state and highly conductive PEDOT:PSS polymer which will provide cations for doping the WO₃. Upon application of a negative voltage to the WO₃ relative to the PEDOT:PSS polymer, the field drives mobile Li⁺ from the PEDOT:PSS polymer into the WO₃, forming n-type WO₃. Unlike the system with PT-PPy layer 3-4, the PEDOT:PSS polymer layer will always be in high conductivity state, even though the WO₃ film will have the same behavior since the higher conductivity occurs only when the mobile Li⁺ cations are driven into the metal oxide phase. Therefore, this structure also has the same a rectifying behavior. There are also challenges with designing a polymer memory to provide competitive performance in terms of storage capacity, density, speed, energy consumption, and reliability. For example, while passive cross-point arrays have been proposed to facilitate manufacturing by isolating memory cells from support circuitry, such passive cross-point arrays suffer from cell-to-cell interference and loading problems. As seen from the foregoing, there continue to be challenges associated with designing and fabricating high performance polymer memories.

### BRIEF DESCRIPTION OF THE DRAWINGS

The present invention may be understood, and its numerous objects, features and advantages obtained, when the following detailed description is considered in conjunction with the following drawings, in which:

FIG. 1 illustrates a simplified schematic diagram of a polymer memory cell structure;

FIG. 2 illustrates a current-voltage characteristics curve for a polymer memory cell structure:

FIGS. 3(a)-3(e) illustrate plan and cross sectional views of a sequence of steps for fabricating an integrated circuit polymer memory in accordance with selected embodiments of the present disclosure;

FIG. 4 illustrates a circuit schematic diagram of a portion of a polymer memory cell array circuit using n-channel access transistors with source lines (SL) running vertically in top metal in accordance with selected embodiments of the present disclosure;

FIG. 5 illustrates a circuit schematic diagram of a portion of a polymer memory cell array circuit using CMOS transmission gate access devices in accordance with selected embodiments of the present disclosure;

FIG. 6 illustrates a plan view of an integrated circuit polymer memory with a layout of staggered cell nodes between pairs of source lines in accordance with selected embodiments of the present disclosure;

FIG. 7 illustrates a circuit schematic diagram of a portion of a polymer memory cell array circuit which includes one bit line for every source line in accordance with the staggered cell node layout embodiments of FIG. 6;

FIG. 8 illustrates a simplified circuit block diagram of a complete polymer memory circuit in accordance with selected embodiments of the present disclosure;

FIG. 9 illustrates a simplified circuit schematic diagram of a row predecoder circuit in accordance with selected embodiments of the present disclosure;

FIG. 10 illustrates a simplified circuit schematic diagram of a main row decoder circuit which receives outputs of the row predecoders and drives word line pairs in accordance with selected embodiments of the present disclosure;

FIG. 11 illustrates a simplified circuit schematic diagram of a column predecoder circuit in accordance with selected embodiments of the present disclosure;

FIG. 12 illustrates a simplified circuit schematic diagram of datapath for current sensing operations in accordance with selected embodiments of the present disclosure;

FIG. 13 illustrates a simplified circuit schematic diagram of current sense amplifier in accordance with selected embodiments of the present disclosure;

FIG. 14 illustrates a simplified circuit schematic diagram of datapath for voltage sensing operations in accordance with selected embodiments of the present disclosure;

FIG. 15 illustrates a simplified circuit schematic diagram of voltage sense amplifier in accordance with selected embodiments of the present disclosure;

FIG. 16 illustrates voltage sensing operations in accordance with selected embodiments of the present disclosure; and

FIG. 17 illustrates a unity gain buffer in accordance with selected embodiments of the present disclosure.

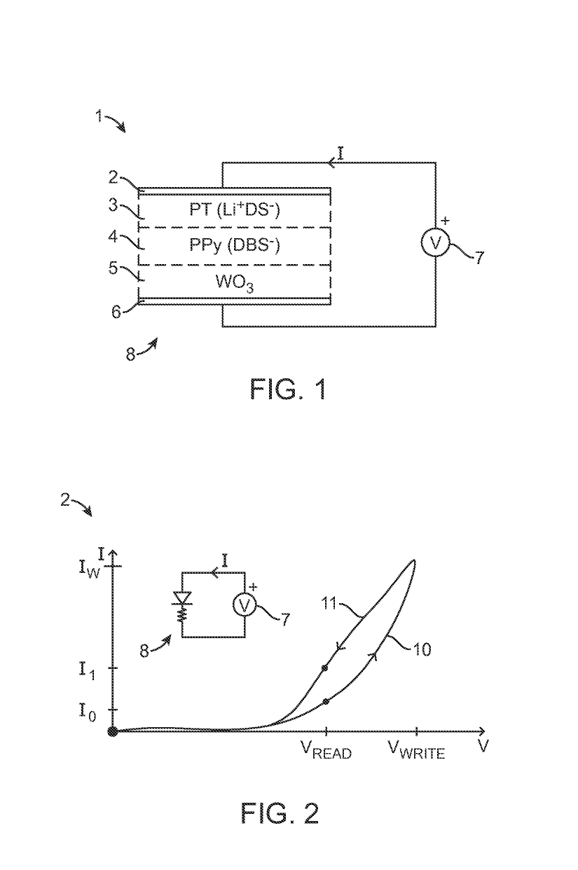

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A high density polymer memory and associated fabrication processes are disclosed to form redox-based polymer memory cell storage nodes as part of the backend CMOS processing steps by using a patterned top or last metal interconnect layer to define source line and cell node electrodes which are selectively processed to form metal oxide layers on the source line electrodes and compensatively-doped, neutral conjugated polymer layer on the cell node electrodes. By forming power supply, row and column decoder, and other circuits for read and write operations in a semiconductor device that is covered by interconnect layers using conventional semiconductor processing, polymer memory materials may be applied to the top layer of interconnect to avoid process integration issues presented by introducing new materials to the semiconductor fabrication processing. In addition, the fabricated semiconductor device circuits may be controlled and activated during the fabrication process to form the polymer memory cell array by selective electrochemical deposition of the metal oxide layer(s) and compensatively-doped, neutral conjugated polymer layer(s) on the patterned source line and cell node electrodes, respectively. In selected embodiments, the memory access circuitry formed in the semiconductor device supports the polymer memory cell fabrication process by providing the ability to selectively activate or bias all source line electrodes at the same time, and to separately selectively activate or bias all cell node electrodes at the same time. Accordingly, there is disclosed herein different polymer memory cell access device embodiments (such as n-channel access transistors or CMOS transmit gate devices) which use row and column decoder circuits for different cell node layouts to support fabrication of redox-based polymer memory cell storage nodes during backend CMOS processing. In addition, there is disclosed a reference cell array of polymer memory cells that are used for current sense and voltage sensing operations.

In this disclosure, an improved system, apparatus, and fabrication method are described for fabricating an array of polymer memory cells in a single, last metal interconnect layer of an integrated circuit wafer that address various problems in the art where various limitations and disadvantages of conventional solutions and technologies will become apparent to one of skill in the art after reviewing the remainder of the present application with reference to the drawings and detailed description provided herein. For example, there are challenges with incorporating polymer materials into existing semiconductor fabrication process flow due to contamination risks and temperature interactions between different materials, as well as difficulties in correctly and quickly reading current values from polymer memory cells. Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of an integrated circuit device without including every device feature or geometry in order to avoid limiting or obscuring the present invention. Such descriptions and representations are used by those skilled in the art to describe and convey the substance of their work to others skilled in the art. In addition, although specific example materials are described herein, those skilled in the art will recognize that other materials with similar properties can be substituted without loss of function. It is also noted that, throughout this detailed description, certain materials will be formed and removed to fabricate the semiconductor structure. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art how to make or use the present invention.

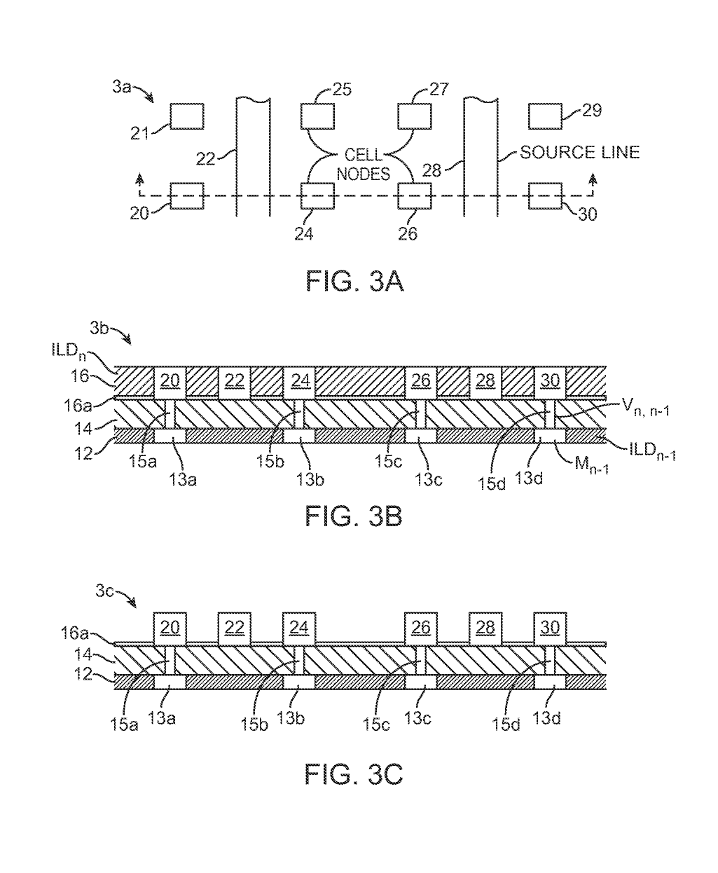

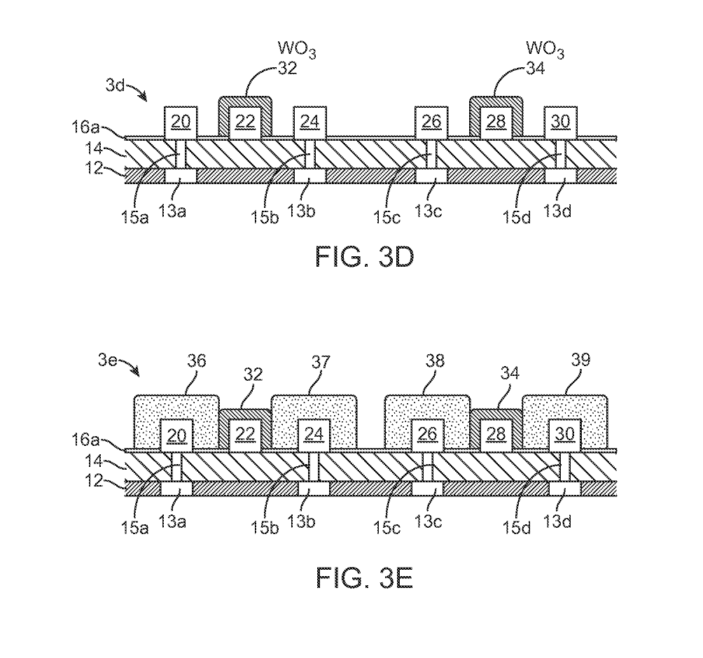

Turning now to FIGS. 3(a)-3(e), there are shown a sequence of steps for fabricating an integrated circuit polymer memory in accordance with selected embodiments of the present disclosure. As a preliminary step, a semiconductor device is manufactured using any desired semiconductor process technology to form transistors, capacitors, and other circuit elements which embody the memory access circuitry for a memory device and which are encapsulated with one or more inter-layer dielectric (ILD) layers. Without belaboring the details, any desired processing steps may be used to fabricate the semiconductor device to include the desired memory access circuitry, including various front end processing steps (such as substrate formation and preparation, sacrificial oxide formation, stripping, isolation region formation, gate dielectric formation, gate electrode patterning and etching, shallow source/drain implantation, spacer formation, deep source/drain implantation, annealing, silicide formation, and polishing steps) and additional backend processing steps (such as forming contact plugs and multiple levels of interconnect(s) (e.g., vias and metal layer conductors formed in different interlevel dielectric layers) that are used to connect the device components in a desired manner to achieve the desired functionality. Thus, the specific sequence of steps used to fabricate the semiconductor device to include the desired memory access circuitry may vary, depending on the process and/or design requirements. It is understood that the terms so used are interchangeable under appropriate circumstances such that the embodiments of the invention described herein are, for example, capable of operation in other orientations than those illustrated or otherwise described herein.

In the semiconductor device, the topmost or last metal interconnect layer may be formed with a conductive material (e.g., copper, tungsten, or aluminum) that is patterned to define thick layers intended for distribution of power to the semiconductor device. As disclosed herein, the last metal interconnect layer is also used to define cell node and source line electrodes in a single layer on which the polymer memory layers are selectively formed or deposited to create polymer memory cells as described hereinbelow. For example, FIG. 3(a) shows a plan view 3a of the top metal layer Mn of a semiconductor device in which columns of individual cell nodes 20-21, 24-27, 29-30 are positioned to share common source line 22, 28. In particular, the cell node electrodes 20-21, 24-25 are disposed symmetrically around a first source line electrode 22, while the cell node electrodes 26-27, 29-30 are disposed symmetrically around a second source line electrode 28. In a general purpose 90 nm CMOS logic process, the minimum width, spacing, and thickness of the top copper metal layer is around 400 nm. Cell nodes 24 and 25 can be placed at the minimum distance from the source line 22, but the spacing between adjacent cell nodes 24, 25, 26, and 27 may be considerably larger to prevent the nodes from being shorted together by the subsequently formed polymer layer(s). However, smaller geometry processes will allow smaller width and spacing between nodes and source lines. With polymer junctions of this size using the cell materials discussed earlier, read currents in the pA range are expected.

Turning now to FIG. 3(b), there is shown a cross sectional view 3b of the semiconductor device shown in FIG. 3(a). Though not shown, it will be appreciated that the memory access circuitry is formed in the underlying substrate and connected through defined interconnect conductors formed in the interlayer dielectric (ILD) layers. To connect the memory access circuitry to a power and/or signal conductors and the subsequently formed polymer memory cells, an interconnect stack of one or more metal interconnect lines and conductive via structures is formed over the semiconductor device in one or more patterned inter-layer dielectric (ILD) layers. For example, the interconnect stack may include a patterned or defined interconnects 13a-d may be formed from a penultimate metal layer Mₙ₋₁ in an interconnect IDL layer 12 (ILDₙ₋₁) by using a damascene process whereby patterned openings in the interconnect IDL layer 12 are filled with a deposited metal layer Mₙ₋₁ and then polished with a chemical mechanical polishing (CMP) process. In selected embodiments, a bottom planarized ILD layer 12 (ILDₙ₋₁) is formed with a suitable deposited dielectric material (e.g., SiO₂, SiOC, SiOF, doped or undoped tetra-ethyl ortho-silicate (BPTEOS), or other low-k dielectric materials) and then patterned and etched to form patterned openings which are filled by depositing and polishing a metal layer (e.g., copper, tungsten, or aluminum), alone or in combination with barrier metal or liner layers, to form the interconnect structures 13a-d. Subsequently, a covering ILD layer 14 is formed on the bottom planarized ILD layer 12 by patterning and etching aligned trench or via openings in which conductive via structures 15a-d are formed by depositing and polishing a conductive via material to fill the trench/via openings. At this point, an etch stop layer 16a (such as SiN, SiC, SiCN, SiON, SiCON, or the like) may be deposited on the entire surface of the semiconductor device to serve as a base for forming the last metal (Mₙ) interconnect level. At this point, a top or last planarized ILD layer 16 (ILDₙ) is formed with a suitable deposited dielectric material and then patterned and etched to form contact openings which are filled by depositing and polishing a last metal layer (e.g., copper, tungsten, or aluminum), alone or in combination with barrier metal or liner layers, to form the last metal interconnect structures 20-30.

When forming the last metal interconnect structures 20-30 with a damascene process, the top or last planarized ILD layer 16 (ILD) formed between the last metal source line electrodes 22, 28 and cell node electrodes 20-21, 24-27, 29-30 must be selectively removed prior to electrochemical deposition of metal oxide and polymer films. The result is illustrated in FIG. 3(c) which shows a cross sectional view 3c of the semiconductor device shown in FIG. 3(a) after a selective etch process is applied to remove the planarized ILD layer 16 and expose the top and sidewall surfaces of the last metal electrodes 20-30. While any selective etch process may be used, selected embodiments of the present disclosure apply a suitable wet or dry etch chemistry which selectively removes the top or last planarized ILD layer 16 (ILD) without removing the last metal layer electrodes 20-30. To control the selective etch process, the etch chemistry is applied to stop at the underlying etch stop layer 16a so that there is no over etch or undercutting of the metal interconnections. With the top and sidewall surfaces of the last metal electrodes 20-30 exposed, the polymer memory layers may be selectively formed at the top interconnect layer without introducing the polymer materials into the previous semiconductor manufacturing steps while also avoiding any high temperature semiconductor processing steps that might adversely interact with the polymer materials.

Turning now to FIG. 3(d), there is illustrated a cross sectional view 3d of the semiconductor device shown in FIG. 3(a) after metal oxide layers 32, 34 are selectively formed on the exposed top and sidewall surfaces of source line electrodes 22, 28. While any metal oxide formation process may be used, selected embodiments of the present disclosure selectively form the metal oxide layer 32, 34 as tungsten oxide (WO₃) to a predetermined thickness of preferably less than 100 nm in the example 90 nm CMOS process, using an electrochemical deposition process wherein the semiconductor device is submerged in a WO₃ precursor solution bath while the source line electrodes 22, 28 are held at a negative potential, ranging from −0.5 to −0.7V-vs Ag/Agcl, with the cell node electrodes 20-21, 24-27, 29-30 floating. Various tungsten oxide electrodeposition processes are known in the art. In one example, a multi-step process is used. After placing the semiconductor device in the plating solution, thin tungsten oxide film layer 32, 34 are electrochemically deposited from a plating bath solution containing Na₂WO₄.2H₂O and H₂O₂ using a constant potential of −0.45V vs Ag/AgCl for 300 s that is applied to only the source line electrodes 22, 28 which are activated by the memory access circuitry. In other embodiments, the potential applied to the source line electrodes 22, 28 is a time-controlled stepped or ramped voltage which is applied to establish a seed layer and then achieve a final plating thickness for the metal oxide layer 32, 34. However, it will be appreciated that other materials and solutions and process conditions may be used. For example, the metal oxide layer 32, 34 may be formed with any passive layer that contains at least one conductivity-facilitating compound that has the ability to donate and accept ions, as long as the material and process of deposition do not have destructive effect on the CMOS metal layer, such as tungsten oxide (WO₃), titanium selenide (TiSe₂), copper sulfide (Cu₂S, CuS), copper oxide (CuO, Cu₂O), manganese oxide (MnO₂), titanium dioxide (TiO₂), indium oxide (I₃O₄), silver sulfide (Ag₂S), and the like. When forming the metal oxide layer 32, 34, any suitable formation process may be used, such as oxidation growth techniques formed via gas phase reactions, electrochemical deposition, spin-on deposition, sputtering, e-beam deposition, thermal deposition process, or an ALD (Atomic Layer Deposition). With any electrodeposition process, the time and/or applied potential may advantageously be controlled to limit the thickness of the metal oxide layer 32, 34 since this layer represents the principal contribution to cell resistance.

Turning now to FIG. 3(e), there is illustrated a cross sectional view 3e of the semiconductor device shown in FIG. 3(a) after one or more conjugated polymer layers 36-39 are selectively formed on the exposed top and sidewall surfaces of cell node electrodes 20-21, 24-27, 29-30, thereby forming a polymer memory cell array on top of the interconnect stack 12-15. Various polymer layer formation processes are known in the art. In one example, a multi-step process is used to selectively form the polymer layers 36-39 by first depositing one or more PEDOT:PSS films using an electrophoretical deposition process from a 1:4 diluted solution of PEDOT, while the cell node electrodes 20-21, 24-27, 29-30 are held at a constant negative potential of −0.5 Vvs Ag/AgCl, with the source line electrodes 22, 28 held at a negative potential. In another example, a multistep process is used to selectively form the polymer layers 36-39 by first depositing a polypyrrole (PPy) layer using an electrochemical deposition process in the presence of Li+-containing electrolyte while the cell node electrodes 20-21, 24-27, 29-30 are held at a positive potential with the source line electrodes 22, 28 held at a negative potential. Next, a polythiophene (PT) layer is electrodeposited in the presence of dodecyl sulfate (DS−) while the cell node electrodes 20-21, 24-27, 29-30 are held at a positive potential with the source line electrodes 22, 28 held at a negative potential. Then the polymer film was doped by allowing the Li⁺ cations to undergo ion exchange with protons in the PSS. This was performed by applying a constant voltage of 0V vs. Ag/AgCl for 500 to 1000 sec in an electrolyte solution of 0.1 M lithium perchlorate (LiClO₄) in propylene carbonate while the cell node electrodes 20-21, 24-27, 29-30 and source line electrodes 22, 28 are hold at a zero potential.

However, it will be appreciated that other materials and solutions and process conditions may be used, as long as the material and process of deposition do not have destructive effect on the CMOS metal layer. For example, the conjugated polymer layers 36-39 may be formed with any active layer having an impedance state that can change (e.g., from a high resistance to a low resistance) when subject to a stimulus, such as a voltage or current, including but not limited to active molecules or molecular groups—such as nitro group, amino group, cyclopentadienyl, dithiolane, methlcyclopentadienyl, fulvalenediyl, indenyl, fluorenyl, cyclobis(paraquart-p-phenylene), bipyridinium, phenothiazine, diazapyrenium, benzonitrile, benzonate, benzamide, carbazole, dibenzothiophene, nitrobenzene, aminobenzenesulfonate, aminobenzoate, molecular units with redox-active metals; metallocenes (Fe, V, Cr, Co, Ni and the like) complex, polypyridine metal complex (Ru, Os and the like)—or polymers—such as polyaniline, polythiophene, polypyrrole, polysilane, polystyrene, polyfuran, polyindole, polyazulene, polyphenylene, polypyridine, polybipyridine, polyphthalocyanine, polysexithiophene, poly(siliconoxohemiporphyrazine), poly(germaniumoxohemiporphyrazine), poly(ethylenedioxythiophene), polyfluorene, polyphenylacetylene, polydiphenylacetylene and related derivatives with active molecular group. Other suitable chemical compounds can also be employed, such as aromatic hydrocarbons, organic molecules with donor and acceptor properties (N-Ethylcarbazole, tetracyanoethylene, cloranol, dinitro-n phenyl), metallo-organic complexes (bisdiphenylglyoxime, bisorthophenylenediimine, tetraaza-tetramethylannulene), porphyrin, phthalocyanine, hexadecafluoro phthalocyanine and their derivatives with active molecular group. In addition, the conjugated polymer layers 36-39 can be selectively formed over the cell node electrodes by organic film growth, chemical vapor deposition (CVD), low pressure chemical vapor deposition (LPCVD), atmospheric pressure CVD (APCVD), plasma enhanced chemical vapor deposition (PECVD), and high density chemical vapor deposition (HDCVD). With any electrochemical deposition processes, the time and/or applied potential may advantageously be controlled to ensure that the PEDOT:PSS film (e.g., 37) touches or makes direct physical contact with the WO₃ metal oxide film (e.g., 32) on the source line electrodes (e.g., 22), but without contacting the PEDOT:PSS film (e.g., 38) on adjacent cell node electrode (e.g., 26), thereby preventing shorts between adjacent memory cells. As will be appreciated, the distance between adjacent cell node electrodes (e.g., 24, 26) must be designed to have sufficient distance to prevent shorts. In selected embodiments, the distance between cell node electrodes and the source line electrodes is generally the minimum design rule allowable in order to reduce cell resistance. In an example 90 nm CMOS process, the minimum spacing of 420 nm between cell node and source line is filled mostly by the polymer layer to minimize cell resistance, since the metal oxide layer is the principal contributor to cell resistance. The metal oxide layer should be 100 nm or less, and the remaining 320 nm or larger gap will be filled by the polymer layers. In selected embodiments, spacing between adjacent nodes should be at least twice the minimum design rule, and preferably three times the minimum design rule to avoid shorts.

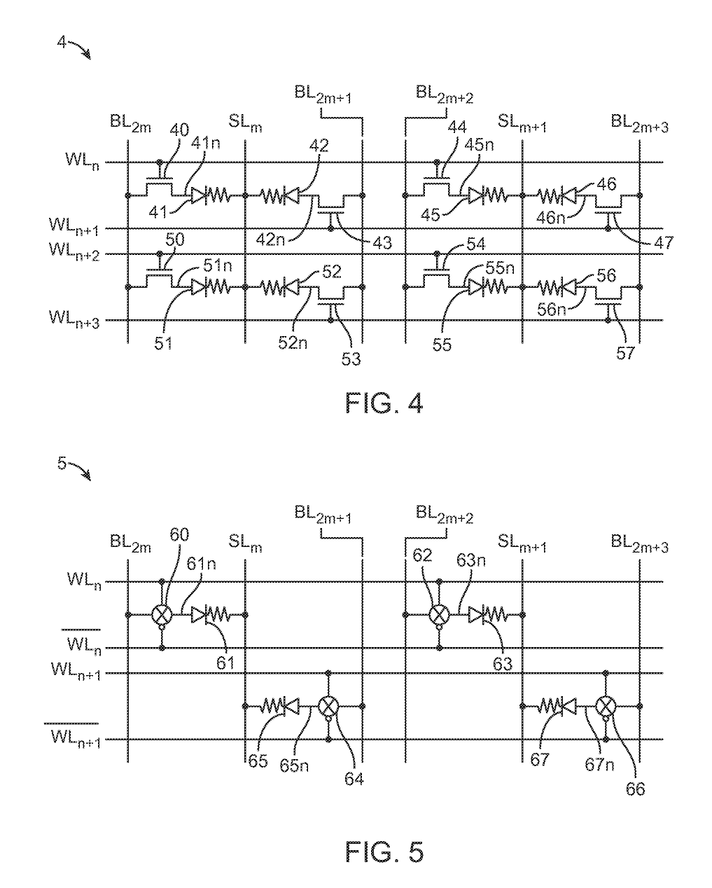

By manufacturing the polymer memory cell array on top of the interconnect stack 12-15 of the semiconductor device, manufacturing complexities from integrating polymer materials into the semiconductor device are avoided. However, each polymer memory cell must still be connected to the memory access circuitry formed in the semiconductor device using one or more memory cell access devices. As will be appreciated, the particular configuration and arrangement of memory cell access devices will depend on the arrangement and layout of the polymer memory cell array. For example, FIG. 4 shows a circuit schematic diagram 4 of a portion of a polymer memory cell array circuit using n-channel access transistors 40, 43-44, 47, 50, 53-54, 57 to access corresponding polymer memory cells 41-42, 45-46, 51-52, 55-56, each of which is connected as shown between source lines (SLₘ, SLₘ₊₁) and corresponding cell nodes 41n, 42n, 45n. 46n, 51n, 52n, 55n. 56n which run vertically in a top or last metal layer in accordance with selected embodiments of the present disclosure corresponding to the top view layout shown in FIG. 3(a). In this configuration, the n-channel access transistors (40, 43-44, 47, 50, 53-54, 57), bit lines (BL₂ₘ, BL₂ₘ₊₁, BL₂ₘ₊₂, BL₂ₘ₊₃), and word lines (WLₙ, WLₙ₊₁, WLₙ₊₂, WLₙ₊₃) are located below the top metal layer (e.g., 20-30 shown in FIG. 3(c)), with each n-channel transistor (e.g., 40) connecting a corresponding cell node (e.g., 41n) of the polymer memory cell (e.g., 41) and bit line (e.g., BL₂ₘ) and being controlled by a word line (e.g., WLₙ) for alternating polymer memory cells in a row such that adjacent pairs of polymer memory cells in a row (e.g., 41, 42) share a common source line (e.g., SLₘ). When using n-channel transistors to implement the memory cell access devices, a boosted voltage may be required to drive the word line (e.g., WLₙ₊₁) for a selected access transistor (e.g., 43) so that there is no voltage drop from the bit line (e.g., BL₂ₘ₊₁) to the cell node (e.g., 42n) of the selected polymer memory cell (e.g., 42).

Another arrangement of the memory cell access devices is shown in FIG. 5 which illustrates a circuit schematic diagram 5 of a portion of a polymer memory cell array circuit using CMOS transmission gate access devices 60, 62, 64, 66 to access corresponding polymer memory cells 61, 63, 65, 67, each of which is connected as shown between source lines (SLₘ, SLₘ₊₁) and corresponding cell nodes 61n, 63n, 65n, 67n which run vertically in a top or last metal layer in accordance with selected embodiments of the present disclosure generally corresponding to the top view layout shown in FIG. 3(a) with alternate cell nodes removed to create sufficient spacing between nodes. In this configuration, the CMOS transmission gate access devices (60, 62, 64, 66) may be implemented with a parallel connection of an n-channel transistor and a p-channel transistor as known in the art, the gates of which are controlled, respectively, by complementary word line signals. In addition, the CMOS transmission gate access devices (60, 62, 64, 66), bit lines (BL₂ₘ, BL₂ₘ₊₁, BL₂ₘ₊₂, BL₂ₘ₊₃), and word lines (WLₙ, WLₙ, WLₙ₊₁, WLₙ₊₁) are located below the top metal layer, with each CMOS transmission gate access device (e.g., 60) connecting a corresponding cell node (e.g., 61n) of the polymer memory cell (e.g., 61) and bit line (e.g., BL₂ₘ) and being controlled by a pair of complementary word lines (WLₙ,W̅L̅ₙ̅) shared by the polymer memory cells in a row such that adjacent polymer memory cells in a row (e.g., 61, 63) are connected to different source lines (e.g., SLₘ, SLₘ₋₁).

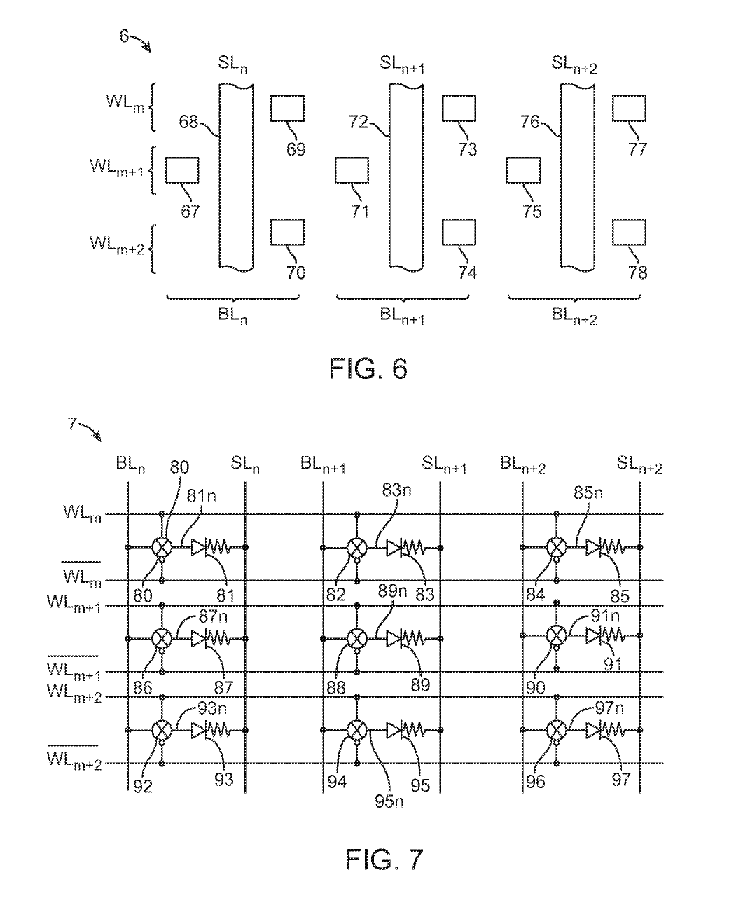

Turning now to FIG. 6, there is shown a plan view 6 of an integrated circuit polymer memory with a layout of staggered cell nodes 67, 69-71, 73-75, 77-78 between pairs of source lines 68, 72, 76 in accordance with selected embodiments of the present disclosure.

In contrast to the aligned layout of cell nodes shown in FIG. 3(a) which requires two bit lines (e.g., BL₂ₘ, BL₂ₘ₊₁) for each source line (e.g., SLₘ), the staggered layout has a single bit line (e.g., BLn) for each source line (e.g., SLₙ). To illustrate an example embodiment of the staggered cell node layout, reference is now made to FIG. 7 which shows a circuit schematic diagram 7 of a portion of a polymer memory cell array circuit which uses CMOS transmission gate access devices 80, 82, 84, 86, 88, 90, 92, 94, 96 to access corresponding polymer memory cells 81, 83, 85, 87, 89, 91, 93, 95, 97, with each column of accessed memory cells (e.g., 80-81, 86-87, 92-93) connected between one bit line (e.g., BLₙ) and a corresponding source line (e.g., SLₙ) such that there is one bit line for every source line. In this arrangement, the source lines (SLₙ, SLₙ₊₁, SLₙ₊₂) and corresponding cell nodes 81n, 83n, 85n, 87n, 89n, 91n, 93n, 95n, 97n are located in a top or last metal layer corresponding to the top view layout shown in FIG. 6, while the CMOS transmission gate access devices (80, 82, 84, 86, 88, 90, 92, 94, 96), which are controlled by complementary word line signals, are located below the top metal layer along with the bit lines (BLₙ, BLₙ₊₁, BLₙ₊₂, BL₂ₘ₊₃) and word lines (WLₘ, W̅L̅ₘ̅, WLₘ₊₁, W̅L̅ₘ̅₊̅₁̅, WLₘ₊₂, W̅L̅ₘ̅₊̅₂̅)). In this way, each CMOS transmission gate access device (e.g., 80) connects a corresponding cell node (e.g., 81n) of the polymer memory cell (e.g., 81) and bit line (e.g., BLₙ) under control of a pair of complementary word lines (WLₘ,W̅L̅ₘ̅) shared by the polymer memory cells in a row such that adjacent polymer memory cells in a row (e.g., 81, 83) are connected to different source lines (e.g., SLₙ, SLₙ₊₁).

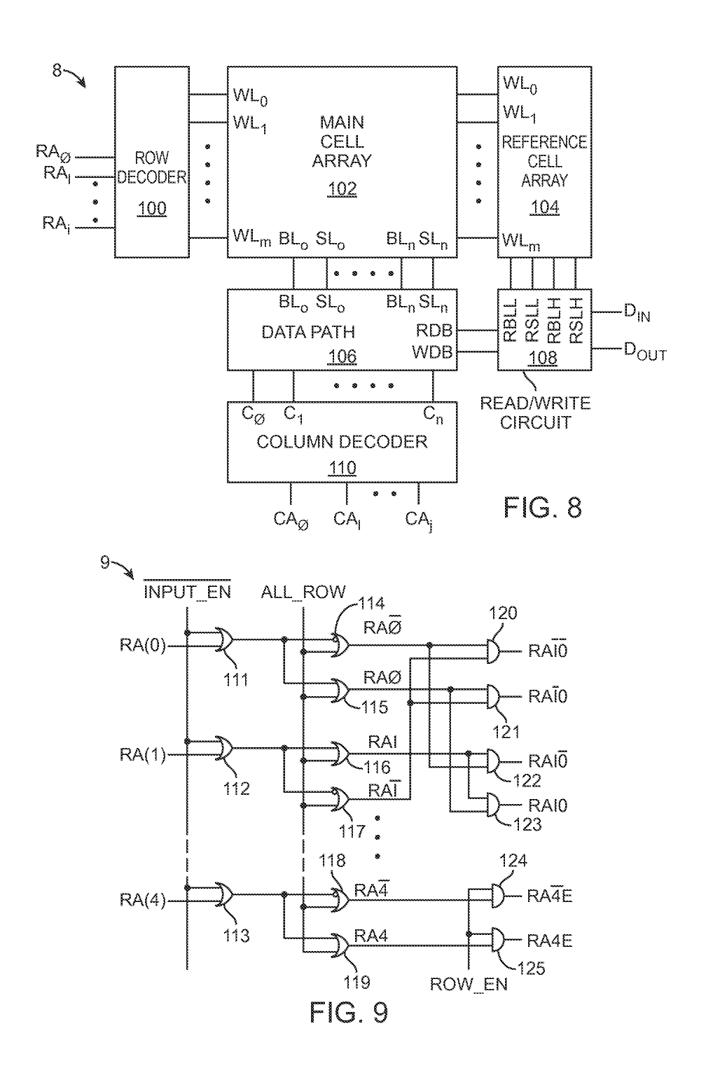

While it will be appreciated that any desired apparatus may be used which includes memory access circuitry for activating the cell node and source line electrodes of the polymer memory array as disclosed herein, FIG. 8 illustrates a simplified circuit block diagram of a complete polymer memory circuit 8 having a memory access circuit which may be used to fabricate and access the polymer memory cell array as disclosed herein. In the depicted polymer memory circuit 8, the memory access circuit is embodied in the row and column decoders 100, 110 and datapath circuit 106, 108 for accessing the main polymer memory cell array 102 and an additional reference cell array 104 which is formed with additional bit lines and source lines. In selected embodiments, the reference cell array 104 is formed with two additional bit lines (e.g., a “Low” reference bit line RBLL, and a “High” reference bit line RBLH) and two additional source lines (e.g., a “Low” reference source line RSLL, and a “High” reference source line RSLH).

Though not shown, it will be appreciated that the polymer memory circuit 8 may also include a conventional interface for receiving and buffering address signals, command signals, and data signals. The command and data signals are conventional and their functions are well known in the art. Examples of command signals include, but are not limited to, Chip Enable (CE) signal(s), Write Enable (WE) signal(s), Output Enable (OE) signal(s), and Clock (CLK) signal(s).

Received row address signals (RA₀, RA₁, . . . RAᵢ) and column address signals (CA₀, CA₁, . . . CAⱼ) are provided to the row decoder 100 and column decoder 110, respectively. The address signals designate locations in a memory array 102 for reading and writing operations as described herein below. To decode the row address signals (RA₀, RA₁, . . . RAᵢ), the row decoder 100 may include a row predecoder (not shown) which provides a predecode row address which the row decoder 100 uses to activate one or more selected word lines (WL₀-WLₘ) during normal operation. In addition, the row decoder 100 may include additional control logic which is used to activate all word lines (WL₀-WLₘ) to turn ON all of the access devices for purposes of biasing the cell nodes of the polymer memory cells to a predetermined voltage for use during device fabrication. The selected word line(s) are used to access or connect one or more addressed memory cells in the array 102 to corresponding bit line(s) selected by the received address.

In similar fashion, the column decoder 110 may decode the column address signals (CA₀, CA₁, . . . CAⱼ) with a column predecoder (not shown) to provide column address signals (C₀, C₁, . . . Cₙ) to the datapath circuit 106 to activate one or more selected bit lines (BL₀-BLₙ) or source lines (SL₀-SLₙ) during normal operation. In addition, the column decoder 110 may include additional control logic which is used with the datapath circuit 106 to activate all bit lines (BL₀-BL_{N}) or all source lines (SL₀-SLₙ) for purposes of biasing the cell node electrodes or source line electrodes, respectively, of the polymer memory cells to a predetermined voltage to perform electroplating during device fabrication.

Once the addressed word lines, bit lines, and source lines are asserted, the main memory cell array 102 and reference cell array 104 are accessed for read or write operations, as well as for purposes of fabricating the polymer memory cells in the arrays 102, 104 by selective application of electroplate bias voltages to the cell node and source line electrodes as described herein. As depicted in the polymer memory circuit 8, the same word lines (WL₀-WLₘ) that drive the main cell array 102 also drive the reference cell array 104. In addition, both of reference bit lines (RBLL, RBLH) are read and written during normal read and write operations on the selected bit line in the main cell array to facilitate the storage and retrieval of data from the main memory cell array 102. In selected embodiments, one reference bit line, RBLL, is always written with ‘0’ data, while the other reference bit line, RBLH, is always written with ‘1’ data. In this way, the reference bit lines are used during the read operation to determine the polarity of data on the selected bit line in the main cell array 102. In other embodiments, each bit of data may be stored differentially in two main memory cells in the main memory cell array 102 as a ‘1’ and a ‘0’—or as a ‘0’ and a ‘1’—in even and odd cells respectively. In this duplicate cell mode of operation for storing each bit differentially in two main memory cells, the reference cell array 104 is not required.

Turning now to FIG. 9, there is shown a simplified circuit schematic diagram of an embodiment of a row predecoder circuit 9 as the first stage of the row decoder (e.g., 100 from FIG. 8) in accordance with selected embodiments of the present disclosure. The depicted row predecoder circuit 9 includes a plurality of logic gates 111-125 which generate and receive logic signals, and which may operate with a supply voltage equal to the write voltage V_{WRITE}. As depicted, the row predecoder 9 provides predecoded row addresses for a memory cell array with 32 word lines (WL₀-WL₃₁) and i=5 row address input signals (RA[0:4]). In addition to the row address input signals, the row predecoder 9 receives a first input enable control signal I̅N̅P̅U̅T̅_̅E̅N̅ which is supplied to the control logic (e.g., input OR gates 111-113) to disable all row address input signals RA[0:4] when the input enable control signal has a first logical value (e.g., I̅N̅P̅U̅T̅_̅E̅N̅=‘1’) to prevent current flow in the input OR gates. Conversely, when the input enable control signal has a second logical value (e.g., I̅N̅P̅U̅T̅_̅E̅N̅=‘0’), the received row address input signals RA[0:4] are combined in pairs with combinatorial control logic (e.g., OR gates 114-119 and AND gates 120-125) to create predecoded row address groups RA10, RA23, and RA4E. The RA10 and RA23 groups each include four signals. With this signal grouping, one of the four signals in each signal group will always be active according to the state of the pair of input row addresses RA[0:4] associated with the group.

The depicted row predecoder 9 also receives a second input control signal ALL_ROW at the input OR gates 111-113 which is applied to the control logic (e.g., OR gates 114-119 and AND gates 120-125). When the second input control signal ALL_ROW has a first logical value (e.g., ALL_ROW=‘1’), the control logic forces all four predecoded addresses in the predecoded row address groups RA10, RA23 high to simultaneously enable all word lines WL₀-WL₃₁ for purposes of accessing the memory cell nodes during the polymer film grow process. However, when the second input control signal ALL_ROW has a second logical value (e.g., ALL_ROW=‘0’), the control logic is operative to perform normal row address predecoding functions.

At the row predecoder 9, a third input control signal ROW_EN is logically combined with the most significant row address input bit RA[4] using control logic (e.g., OR gates 118-110 and AND gates 124-125) to generate the final predecoded row address group RA4E which includes signals. RA4E. RA4E. If the depicted control logic receives the third input control signal ROW_EN having a first logical value (e.g., ROW_EN=‘1’), then either one or all word lines will be activated, depending on the state of the second input control signal ALL_ROW. Conversely, all word lines will be deactivated if the third input control signal ROW_EN has a second logical value (e.g., ROW_EN=‘0’).

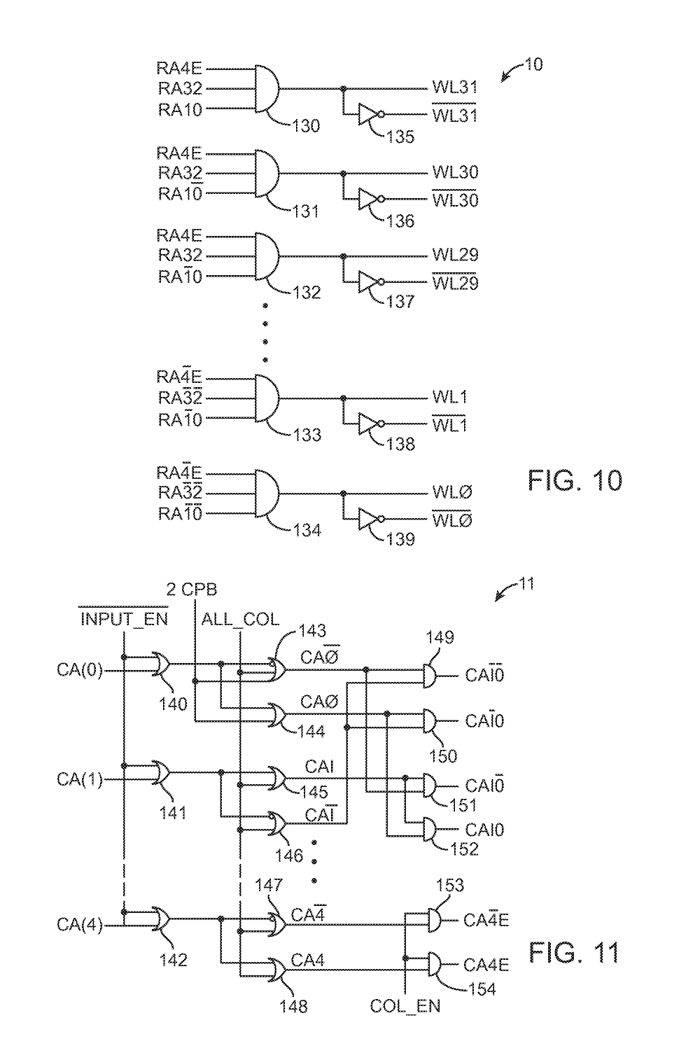

Turning now to FIG. 10, there is shown a simplified circuit schematic diagram of an embodiment of a main row decoder circuit 10 which receives the outputs of the row predecoders (e.g., row predecoder 9 from FIG. 9) and drives the associated word line pairs in accordance with selected embodiments of the present disclosure. The depicted row decoder circuit 10 includes a plurality of logic gates 130-134 and inverters 135-139 which may be connected as shown to generate and receive logic signals. As depicted, the row decoder 10 receives output signals from the predecoded row address groups RA10, RA32, and RA4E generated at the row predecoder. The received row predecoder outputs are processed at the control logic which may include a plurality of three-input AND gates 130-134, each of which is connected to receive one predecoded row address signal from each of the predecoded row address groups RA10, RA32, and RA4E. Each three-input AND gate (e.g., 130) generates an output (e.g., WL₃₁) and an inverted output (e.g., W̅L̅₃̅₁̅) from an associated inverter (e.g., 135). In this way, the main row decoder drives 32 complementary word line pairs.

Turning now to FIG. 11, there is shown a simplified circuit schematic diagram of an embodiment of a column predecoder circuit 11 as the first stage of the column decoder (e.g., 110 from FIG. 8) in accordance with selected embodiments of the present disclosure. The depicted column predecoder circuit 11 includes a plurality of logic gates 140-154 which generate and receive logic signals with a circuit arrangement that is functionally identical to the row predecoder circuit 9 shown in FIG. 9, except for the receipt and processing of the storage control signal 2CPB which indicates whether two cells per bit will be used to store data bits in the main memory array. As depicted, the column predecoder circuit 11 provides a predecode column address for a memory cell array with 32 word lines (WL₀-WL₃₁) and j=5 column address input signals (CA[0:4]). In addition to the column address input signals, the column predecoder circuit 11 receives a first input enable control signal I̅N̅P̅U̅T̅_̅E̅N̅ which is supplied to the control logic (e.g., input OR gates 140-142) to disable all column address input signals CA[0:4] when the input enable control signal has a first logical value (e.g., I̅N̅P̅U̅T̅_̅E̅N̅=‘l’) to prevent current flow in the input OR gates. Conversely, when the input enable control signal has a second logical value (e.g., I̅N̅P̅U̅T̅_̅E̅N̅=‘0’), the received column address input signals CA[0:4] are combined in pairs with combinatorial control logic (e.g., OR gates 143-148 and AND gates 149-154) to create predecoded column address groups CA10, CA23, and CA4E. With this signal grouping, one of the four signals in each signal group will always be active according to the state of the pair of input column addresses CA[0:4] associated with the group.

The depicted column predecoder 11 also receives a second input control signal ALL_COL at the input OR gates 143-148 which is applied to the control logic (e.g., OR gates 114-119 and AND gates 149-154). When the second input control signal ALL_COL has a first logical value (e.g., ALL_COL=‘1’), the control logic forces all four predecoded addresses in the predecoded column address groups CA10, CA23 high for purposes of accessing the memory source lines during the polymer film grow process. However, when the second input control signal ALL_COL has second logical value (e.g., ALL_COL=‘0’), the control logic is operative to perform normal column address predecoding functions.

At the column predecoder 11, a third input control signal COL_EN is logically combined with the most significant column address input bit CA[4] using control logic (e.g., OR gates 147-148 and AND gates 153-154) to generate the final predecoded column address group CA4E which includes signals, CA4E, CA4E. If the depicted control logic receives the third input control signal COL_EN having a first logical value (e.g., COL_EN=‘1’), then either one or all source lines will be activated, depending on the state of the second input control signal ALL_COL. Conversely, all source lines will be deactivated if the third input control signal COL_EN has a second logical value (e.g., COL_EN=‘0’).

At the column predecoder 11, the storage control signal 2CPB is logically combined with the least significant column address input bit CA[0] and the second input control signal ALL_COL using control logic (e.g., three-input OR gates 143-144 and AND gates 149-150) to indicate whether the memory array will store one bit of information in one or two memory cell locations. If the storage control signal 2CPB has a first logical value (e.g., 2CPB=‘1’), then the memory array will store one bit of information differentially in two adjacent memory cells. By applying the storage control signal 2CPB=‘1’ to three-input OR gates 143-144, the input column address CA0 is ignored, and two signals in the group CA10 will be activated, depending on input column address CA1. However, if the storage control signal 2CPB has a second logical value (e.g., 2CPB=‘0’), then the memory array will store one bit of information in one memory cell.

Though not shown, it will be appreciated that the outputs of the column predecoder 11 may be received and processed by a main column decoder that is functionally identical to the main row decoder shown in FIG. 10, except that no inverted column decoder outputs are required.

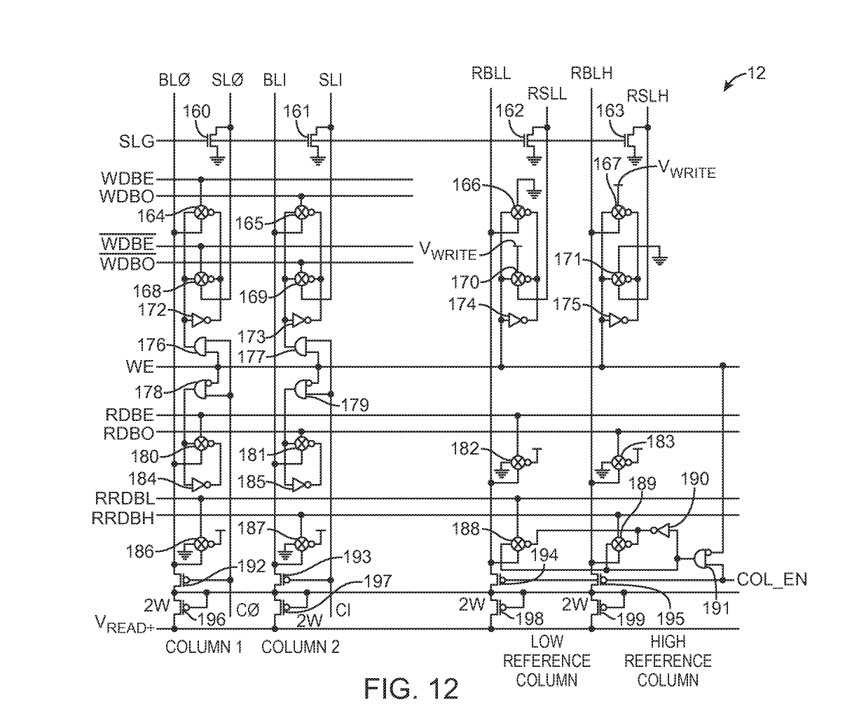

Turning now to FIG. 12, there is shown a simplified circuit schematic diagram of datapath circuit 12 for current sensing operations in accordance with selected embodiments of the present disclosure. The depicted datapath circuit 12 includes read and write control logic and access circuitry 160-199 for only selected columns (e.g., column 0 and column 1) for the main memory cell array along with the reference low and the reference high columns for the reference cell array. While the depicted columns (column 0 and column 1) are selected by corresponding column decoder outputs (C0 and C1), it will be appreciated that additional even and odd columns are selected by corresponding column decoder outputs (C2, C3, C4, . . . Cn−1).

In operation, all source lines (e.g., SL₀, SL₁, RSLL, RSLH, etc.) are held at a ground potential through n-channel transistors 160-163 which are controlled by a source line ground (SLG) signal which is controlled to be active during read operations and inactive during write operations.

To support both one-cell-per-bit and two-cell-per-bit operations, each column is provided with databus pairs WDBE/W̅D̅B̅E̅ and WDBO/W̅D̅B̅O̅. During one-cell-per-bit operation, a single column decoder output (e.g., C0 or C1) will be activated, and the same data will be provided on the WDBE/W̅D̅B̅E̅ and WDBO/W̅D̅B̅O̅ pairs. In the datapath circuit 12, control logic (e.g., AND gates 176 or 177) combines the activated column decoder output (e.g., C0 or C1) with the write enable signal WE to enable a first transmission gate (e.g., 164 or 165) to connect the WDBE or WDBO signal to the selected bit line (e.g., BL₀ or BL₁) and to enable a second transmission gate (e.g., 168 or 169) to connect the WDBE or WDBO signal to the selected source line (e.g., SL₀ or SL₁). However, during two-cell-per-bit operation, two adjacent odd and even column decoder outputs (e.g., C0 and C1) will be activated, and the opposite data will be provided on the WDBE/W̅D̅B̅E̅ and WDBO/W̅D̅B̅O̅ pairs. In this way, V_{WRITE}/ground will be applied to one bit line/source line pair, and ground/V_{WRITE} will be applied to the other bit line/source line pair, depending on the write data bit.

During one-cell-per-bit read operations, control logic at the datapath circuit 12 connects a selected bit line (e.g., BL₀ or BL₁) to either an “odd” read data bus RDBO or “even” read data bus RDBE through a transmission gate (e.g., 180, 181) that is controlled by an AND gate (e.g., 178, 179) and inverted output thereof (e.g., from inverters 184, 185), where the AND gate receives the activated column decoder output (e.g., C0, C1) and the inverted write enable signal WE. In two-cell-per-bit read operations, two column decoder outputs (e.g., C0 and C1) will be activated, and an odd and even bit line (e.g., BL₀ and BL₁) will be connected across transmission gates (e.g., 180, 181) to RDBE and RDBO, respectively.

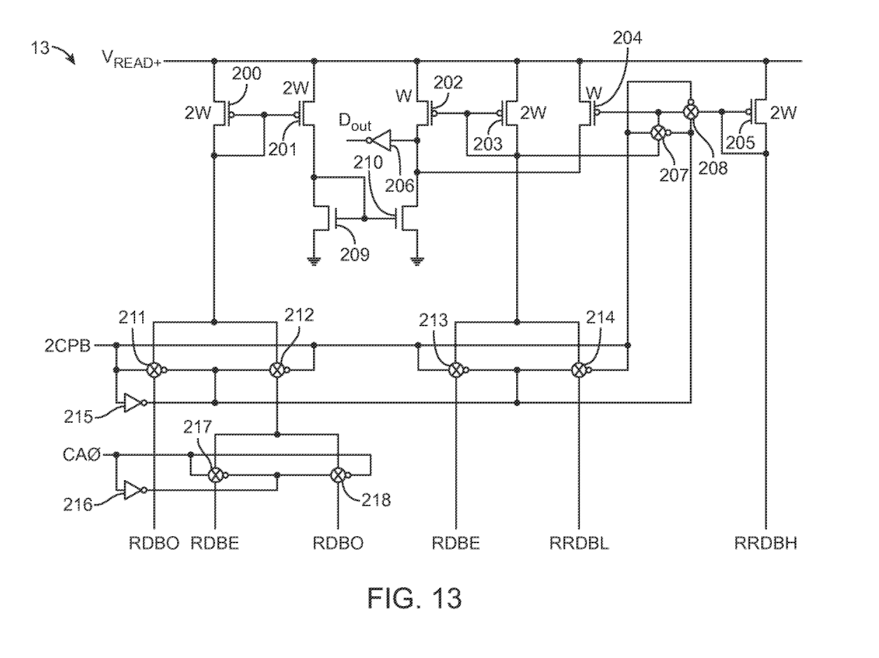

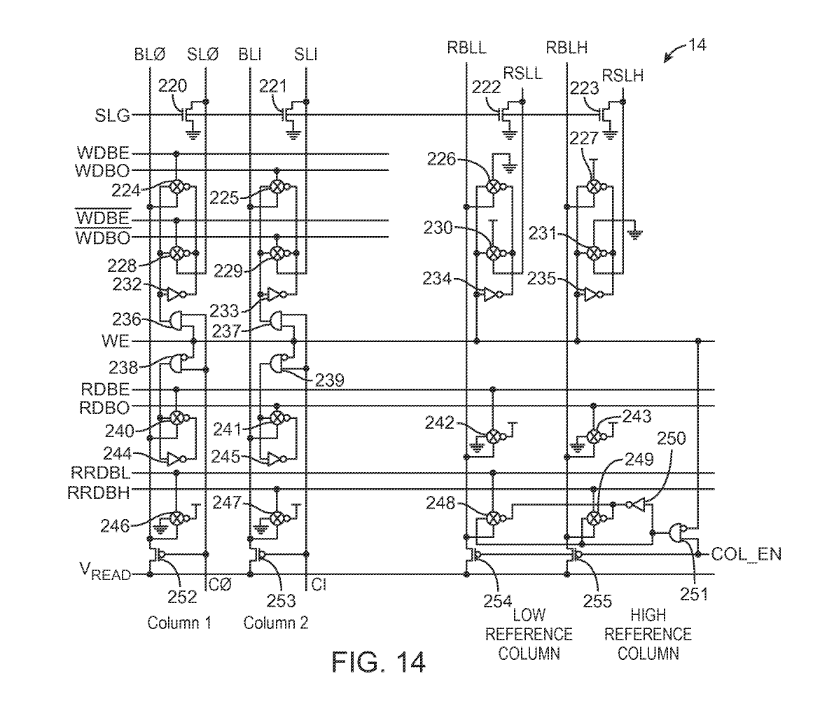

During current sensing read operations, the datapath circuit 12 holds all unselected bit lines at a potential of V_{READ} by applying the deactivated column decoder outputs (e.g., C1=‘0’) to the gates of the PMOS connection transistors (e.g., 193) which connect the unselected bit lines (e.g., BL₁) to a p-channel source follower circuit (e.g., parallel transistors 196-199, etc.). By connecting the unselected bit lines (e.g., BL₁) to the p-channel source follower circuit, current in the inactive columns (e.g., C1) will flow from the source followers through the memory cells enabled by the active word line to ground. In the active column (e.g., C0)—or active two columns in the case of two-cell-per-bit operation)—current will flow from one (or two) source followers (e.g., 200, 203 shown in FIG. 13) in the current sense amplifier through the accessed memory cell(s) to ground. During uninterrupted read operations at the datapath circuit 12, current will be constantly flowing through memory cells enabled by the activated word line(s), and the voltage on all of the bit lines, both selected and unselected, will be held substantially at V_{READ}.

To support read and write operations, the datapath circuit 12 also includes two reference columns. A first or “low” reference column includes reference cells that are always written to a ‘0’ state, while a second or “high” reference column includes reference cells that are always written to a ‘1’ state. During write operations (e.g., WE=‘1’), a “low” reference bit line RBLL in the first or “low” reference column is connected to ground through a transmission gate (e.g., 166) which is controlled by the write enable WE signal and an inverted W̅E̅ signal generated by an inverter (e.g., 174). In addition, a “Low” reference source line RSLL in the first or “low” reference column is connected to V_{WRITE} through a transmission gate (e.g., 170) which is controlled by the write enable WE signal and the inverted W̅E̅ signal generated by an inverter (e.g., 174) to write a ‘0’ into the “low” reference memory cell connected to the active word line. In similar fashion, a “high” reference bit line RBLH is connected to V_{WRITE} through a transmission gate (e.g., 167) and a “high” reference source line RSLH is connected to ground through a transmission gate (e.g., 171) during write operations to write a ‘1’ into the “high” reference cell connected to the active word line.

The datapath circuit 12 includes a first transmission gate (e.g., 188) for connecting the RBLL line to a “low” reference read data bus RRDBL, and also includes a second transmission gate (e.g., 189) for connecting the RBLH line to a “high” reference read data bus RRDBH when the column decoders are enabled by the input column enable control signal COL_EN which is applied to the AND gate (e.g., 191) which also receives the inverted write enable WE signal. During one-cell-per-bit operation, the datapath circuit 12 uses the RRDBL and RRDBH lines in the current sense amplifier to determine whether the accessed cell holds ‘0’ or ‘1’ data.

In selected embodiments, the datapath circuit 12 balances the capacitive load on the RDBO/E and RRDBL/H data busses by connecting dummy transmission gates to the RDBO/E data busses in the reference array and to the RRDBL/H data busses in the main cell array. For example, continuously deactivated first and second dummy transmission gates (e.g., 182, 183) are connected, respectively, to the RDBE and RDBO data busses in the reference array. In similar fashion, continuously deactivated dummy transmission gates (e.g., 186, 187) are connected, respectively, to the RRDBL and RRDBH data busses in the main cell array.

Turning now to FIG. 13, there is shown a simplified circuit schematic diagram of current sense amplifier 13 in accordance with selected embodiments of the present disclosure. The depicted current sense amplifier 13 includes read control logic and access circuitry 200-218 connected as shown to read stored data from the main memory cell array based on comparative reference data in the reference high columns for the reference cell array. As illustrated, the storage control signal 2CPB is applied to the depicted configuration of transmission gates 207-208, 211-214 and an inverter (e.g., 215) while the column address signal (e.g., CA0) is applied to the transmission gates 217-218 and an inverter (e.g., 218), thereby switching appropriate data busses based on the storage mode.

During one-cell-per-bit storage mode, current in either the “even” read data bus RDBE or “odd” read data bus RDBO is selected by the least significant column address CA0 which controls the transmission gates 217, 218 to provide current from the selected column to a p-channel current mirror 200, 201 in the current sense amplifier 13. In addition, half of the reference low current (at “low” reference read data bus RRDBL) and half of the reference high current (at “high” reference read data bus RRDBH) are summed with p-channel current mirror 202, 203 and p-channel current mirror 204, 205 which have gate electrodes coupled together by the enabled transmission gates 208. This is accomplished by having current mirror input transistors (e.g., 203, 205) having a width of 2 W while the output transistors (e.g., 202, 204) have a width of W to provide (10+11)/2 to a current summing node at the input of inverter 206. The left side current (from p-channel transistor 201) is provided to the current summing output node through an n-channel current mirror 209, 210. Inverter 206 coupled to the current summing node provides the final read data output Dout.

During two-cell-per-bit storage mode, the current in “odd” read data bus RDBO is mirrored on the left side of the current sense amplifier 13, and the current in “even” read data bus RDBE is mirrored on the right side of the current sense amplifier 13. However, the storage control signal 2CPB is applied to control the gate-coupling transmission gates 207, 208 so that the right side the RDBE current mirror input node is switched to both half-sized output mirrors to provide a current gain of “l” to the output node. As explained above, the reference columns are not used in two-cell-per-bit storage mode.

The two-cell-per-bit storage mode is expected to have a more robust cell retention because the current sense amplifier 13 always compares current I₀ with current I₁. In contrast, the current sense amplifier in the one-cell-per-bit storage mode must discriminate between either current I₀ or current I₁ with a reference level equal to (I₀+I₁)/2. Even under ideal conditions for the one-cell-per-bit storage mode, the stored data signal is half that of two-cell-per-bit storage mode of operation. In addition, as the ‘1’ level in the cell decays as a function of the retention time of the polymer junction, the signal becomes worse. To compensate for this, selected embodiments of the present disclosure will bias the threshold level closer to the ‘0’ level, such as (2I₀+I₁)/3 or even (3I₀+I₁)/4. This can be accomplished by appropriately adjusting the reference current mirror ratios.

As will be appreciated, other memory access circuits may be used to sense the data values stored in the main memory array. For example, FIG. 14 illustrates a simplified circuit schematic diagram of datapath circuit 14 for voltage sensing operations in accordance with selected embodiments of the present disclosure. The depicted datapath circuit 14 includes read and write control logic and access circuitry 220-255 connected as shown for accessing selected columns (e.g., column 0 and column 1) for the main memory cell array along with the reference low and the reference high columns for the reference cell array. In operation and design, the datapath circuit 14 is functionally identical to the datapath circuit 12 shown in FIG. 12 except for the precharge circuitry 252-255 used to connect the bit lines to the read voltage V_{READ} as described below. In particular, the source lines (e.g., SL₀, SL₁, RSLL, RSLH, etc.) are held at a ground potential through n-channel transistors 220-223 which are controlled by a source line ground (SLG) signal which is controlled to be active during read operations and inactive during write operations. In addition, each column is provided with databus pairs WDBE/W̅D̅B̅E̅ and WDBO/W̅D̅B̅O̅ to support both one-cell-per-bit and two-cell-per-bit operations substantially as described hereinabove. During one-cell-per-bit operation, control logic (e.g., AND gates 236, 237) in the datapath circuit 14 combines the activated column decoder output (e.g., C0 or C1) with the write enable signal WE to enable a first transmission gate (e.g., 224 or 225) to connect the WDBE or WDBO signal to the selected bit line (e.g., BL₀ or BL₁) and to enable a second transmission gate (e.g., 228 or 229) to connect the W̅D̅B̅E̅ or W̅D̅B̅O̅ signal to the selected source line (e.g., SL₀ or SL₁). However, during two-cell-per-bit operation, two adjacent odd and even column decoder outputs (e.g., C0 and C1) will be activated, and the opposite data will be provided on the WDBE/W̅D̅B̅E̅ and WDBO/W̅D̅B̅O̅ pairs. In this way, V_{WRITE}/ground will be applied to one bit line/source line pair, and ground/V_{WRITE} will be applied to the other bit line/source line pair, depending on the write data bit.

During one-cell-per-bit read operations, control logic at the datapath circuit 14 connects a selected bit line (e.g., BL₀or BL₁) to either an “odd” read data bus RDBO or “even” read data bus RDBE through a transmission gate (e.g., 240, 241) that is controlled by an AND gate (e.g., 238, 239) and inverted output thereof (e.g., from inverters 244, 245), where the AND gate receives the activated column decoder output (e.g., C0, C1) and the inverted write enable signal WE. In two-cell-per-bit read operations, two column decoder outputs (e.g., C0 and C1) will be activated, and an odd and even bit line (e.g., BL₀ and BL₁) will be connected across transmission gates (e.g., 240, 241) to RDBE and RDBO, respectively.

To facilitate voltage sensing read operations, the datapath circuit 14 includes precharge circuitry 252-255 which is controlled by the column address signals C0, C1, etc, and input control signal COL_EN to selectively precharge the bit lines (e.g., BL₀, BL₁, RBLL, RBLH, etc.) to a V_{READ} potential. In particular, when the input control signal COL_EN is low, all column addresses C0, C1, etc, are deselected by virtue of all source lines being deactivated as described above with reference to FIG. 11. In addition, the “low” input control signal COL_EN applied to the n-channel transistors 254, 255 precharges the bit lines RBLL, RBLH to V_{READ}. However, when a column is selected and the input control signal COL_EN is high, the precharge is turned OFF and the charge on the bit lines RBLL, RBLH is discharged through the selected reference memory cell. The slope of the discharge ramp depends on whether the accessed cell is a ‘1’ or a ‘0’. In two-cell-per-bit mode, one of the bit lines will always be ‘1’ and the other ‘0’. In one-cell-per-bit mode, the “high” reference bit line RBLH and the “low” reference bit line RBLL are used to provide a ramp that falls between the ‘0’ ramp and ‘1’ ramp.

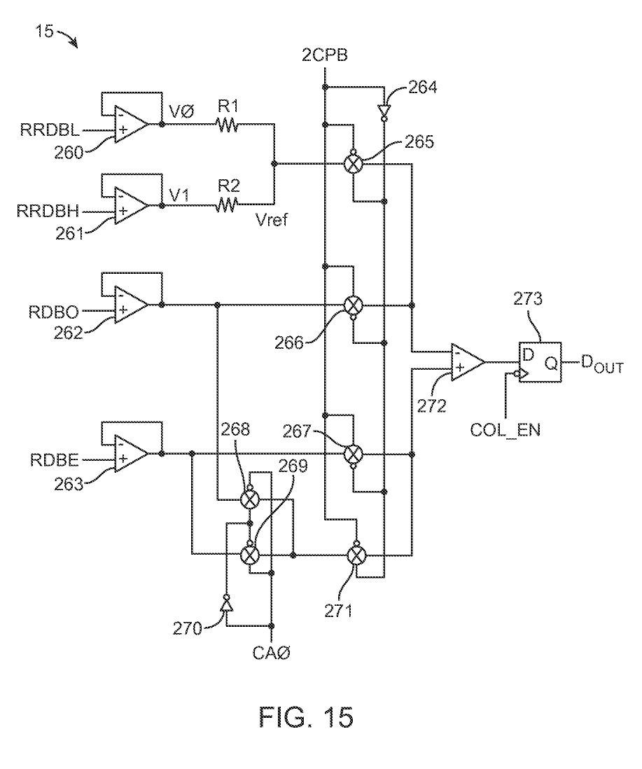

Turning now to FIG. 15, there is illustrated a simplified circuit schematic diagram of a voltage sense amplifier 15 in accordance with selected embodiments of the present disclosure. The depicted voltage sensing circuit 15 includes an array of bit line amplifier circuits 260-263 connected with a resistor divider R1, R2 across a transmission gate circuit 264-271 to supply even and odd read data bus values and a reference voltage V_{REF} as inputs to a comparator circuit 272 having an output that is latched with an output D-flip flop latch 273.

In a one-cell-per-bit operation mode, the resistor divider sums the voltage on the reference high bit line RBLH and the voltage on the reference low bit line RBLL to provide reference voltage Vref. In addition, the amplifier circuits 260-263 may each be implemented as unity gain buffers to provide equal capacitive loading on all of the bit lines RRDBL, RRDBH, RDBO, RDBE. The buffered outputs V0, V1 from low and high reference read data bus values RRDBL, RRDBH are respectively applied to the resistors R1 and R2 in the a resistor divider R1, R2 to provide a reference voltage V_{REF}=V0*R2/(R1+R2)+V1*R1/(R1+R2). If resistors R1 and R2 are equal, the ramp falls halfway between the ‘0’ ramp V0 and ‘1’ ramp V1. In selected embodiments, cell decay compensation may be achieved by biasing the reference voltage V_{REF} more closely to the ‘0’ ramp V0, such as by setting R2=2*R1 or even R2=3*R1.

In the one-cell-per-bit mode, the storage control signal 2CPB controls the transmission gate circuit 264-271 to select the resistor divider V_{REF} and either the even column RDBE or odd column RDBO, depending on the least significant address bit CA0, for input to the comparator circuit 272. However, in the two-cell-per-bit mode, the transmission gate circuit 264-271 responds to the storage control signal 2CPB to provide the even and odd columns to the comparator circuit 272. The output of the comparator circuit 272 is latched by a flip-flop 273 when the column enable signal COL_EN is deactivated to provide the data output signal Dout.

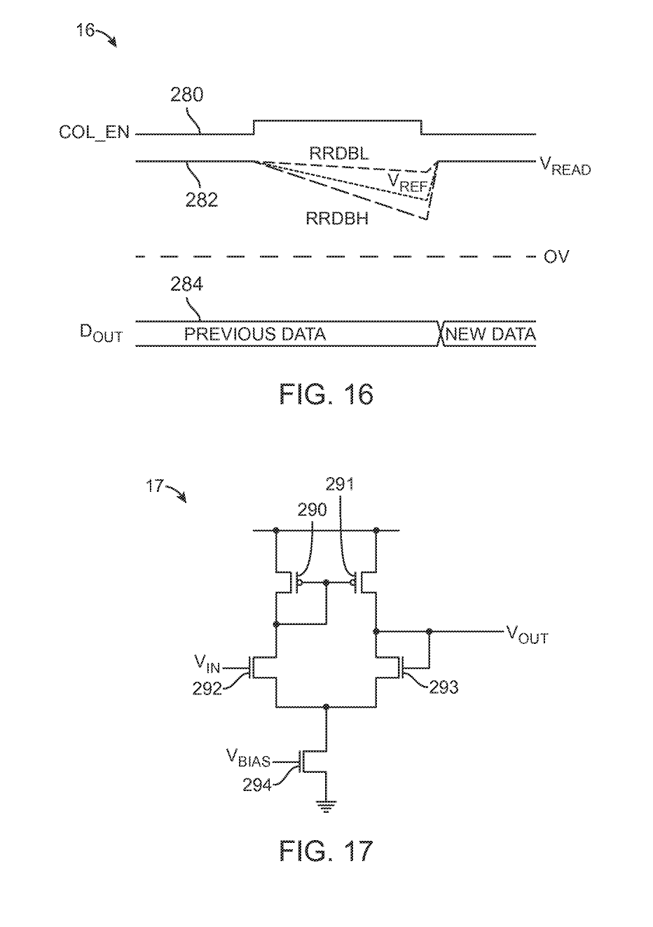

To illustrate the operation of the voltage sensing operations, reference is now made to FIG. 16 which illustrates a timing diagram of the column enable signal COL_EN and the bit lines signal levels during data read operations in accordance with selected embodiments of the present disclosure. As illustrated, when the COL_EN signal 280 is LOW, the (reference) bit line signals 282 are held at V_{READ} by the precharge circuitry 252-255. When the COL_EN signal 280 goes HIGH, the (reference) bit lines 282 start to ramp towards the ground potential. As illustrated, the “low” reference read data bus RRDBL has the slowest ramp and the “high” reference read data bus RRDBH has the fastest ramp. As will be appreciated, a main memory array bit line connected to a cell storing ‘0’ data would have a similar ramp as RRDBL, while a main memory array bit line connected to a cell storing ‘1’ data would have a similar ramp as RRDBH. The ramp on the reference voltage V_{REF} generated by the resistor divider R1, R2 falls between the two extremes. If the COL_EN signal 280 is held HIGH for too long, all the (reference) bit line values will reach ground (e.g., 0V), at which point it will no longer be possible to discriminate the cell data. Accordingly, the COL_EN signal 280 should be deactivated (e.g., return to the LOW state) before the RRDBH and a column with ‘1’ data reaches ground so that the existing or previous data can be read at the output latch signal Dout 284. After the COL_EN signal 280 is deactivated, new data can be loaded and retrieved at the output latch signal Dout 284.

As will be appreciated from the present disclosure, the row and column addresses must be held constant during voltage sensing operations, such as described with reference to FIGS. 14-15. However, with current sensing operations such as described with reference to FIGS. 12-13, the row and column addresses can be changed anytime during operation, and it is only a matter of time for the circuit to provide the correct data.

Turning now to FIG. 17, there is illustrated a simplified circuit schematic diagram of a unity gain buffer 17 such as may be used for the bit line amplifier circuits 260-263 shown in FIG. 16 in accordance with selected embodiments of the present disclosure. The depicted unity gain buffer 17 may include a differential NFET amplifier that includes two n-channel transistors 292, 293, with the gate of the n-channel transistor 292 connected to receive the input voltage Vin, and with the gate and drain of the n-channel transistor 293 connected to generate and receive the output voltage Vout. The drain nodes of each n-channel transistor 292, 293 may be coupled to a current mirror which is formed with two p-channel transistors 290, 291 having their gates connected in common to the drain of the n-channel transistor 292. In addition, the source nodes of each n-channel transistor 292, 293 may be coupled in common to a bias transistor 294 which connects the differential NFET amplifier to ground under control of a bias voltage Vbias. As will be appreciated, Vbias may supplied by a current mirror circuit (not shown) although the positive power supply voltage V_{WRITE} will also work.

As seen from above, selected embodiments of a polymer memory are described in which memory access circuitry is controlled during the fabrication process to electroplate polymer memory film layers on the cell node and source line electrodes formed in the last metal layer so that the polymer memory film layers are isolated by the interconnect stack from the underlying semiconductor circuitry. Employing a dual damascene process to form the multi-level interconnect structure, cell node and source line electrodes in the last metal layer are exposed and selectively plated with the polymer memory film layers so that one or more conjugated polymer films formed on cell node electrodes touch or make direct physical contact with a metal oxide film formed on the source line electrodes, but without contacting the conjugated polymer film(s) formed on adjacent cell node electrodes. In addition, examples of memory access circuits (e.g., row decoder, column decoder, and datapath circuits) have been disclosed and described for suitable use in both normal read and write operations, as well as for use in controlling the electroplating polymer memory film layers on the cell node and source line electrodes during fabrication. Broadly speaking, the disclosed memory access circuits enable the source line electrodes to be held at a negative potential while the cell node electrodes are floating during formation of a metal oxide layer on the source line electrodes, and also enable the cell node electrodes to be held at a positive potential while the source line electrodes are held at a negative potential during formation of one or more polymer layers on the cell node electrodes.

By now it should be appreciated that there is provided herein an integrated circuit device with a polymer memory array formed on an interconnect stack and associated fabrication process. The disclosed integrated circuit device includes a semiconductor substrate (e.g., SOI or bulk silicon) having one or more active circuits. The integrated circuit device also includes a multi-level interconnect structure formed on the semiconductor substrate to isolate the one or more active circuits with multiple interconnect levels. As formed, the multi-level interconnect structure includes an upper interconnect level (e.g., last metal layer formed with copper) in which a plurality of cell node electrodes and a plurality of source line electrodes are formed in an array. The integrated circuit device also includes an array of polymer memory cells formed in the upper interconnect level. As formed, each polymer memory cell includes a passive layer comprising at least one conductivity-facilitating compound that is formed on top and sidewall surfaces of a source line electrode. For example, the passive layer may be formed with metal oxide layer selected from the group consisting of tungsten oxide (WO₃), molybdenum oxide (MoO₃), titanium selenide (TiSe₂), copper sulfide (Cu₂S, CuS), copper oxide (CuO, Cu₂O), manganese oxide (MnO₂), titanium dioxide (TiO₂), indium oxide (I₃O₄), silver sulfide (Ag₂S), and iron oxide (Fe₃O₄). In addition, each polymer memory cell includes an active layer having an impedance state that can change that is formed on top and sidewall surfaces of an adjacent cell node electrode with sufficient thickness to make direct physical contact with the passive layer. For example, the active layer may be formed with one or more conjugated polymer layers, such as a poly(3,4-ethylenedioxythiophene)-poly(styrenesulfonate) layer formed on top and sidewall surfaces of the adjacent cell node electrode to make direct physical contact with the passive layer, or a polythiophene layer formed on top and sidewall surfaces of the adjacent cell node electrode, and a polypyrrole layer formed on the polythiophene layer to make direct physical contact with the passive layer. The active circuits formed in the substrate may include embedded memory access circuitry which may be activated during fabrication of the integrated circuit device to selectively float or bias the plurality of cell node electrodes to a first bias voltage while simultaneously floating or biasing the plurality of source line electrodes to a second bias voltage during formation of the passive layer or active layer.

In another form, there is provided an integrated circuit device with a polymer memory array formed on an interconnect stack and associated fabrication process. The disclosed integrated circuit device includes a semiconductor substrate on which one or more active circuits are formed. In addition, the integrated circuit device includes a multi-level interconnect structure formed on the semiconductor substrate which has an upper interconnect level. In the upper interconnect level, a plurality of storage elements are formed in an array, where each storage element includes a first electrode and a second electrode formed in the upper interconnect level at laterally different locations, with the first electrode being connected to an access device formed in the semiconductor substrate, and with the second electrode being in contact with or forming an integral part of an interconnect line in the upper interconnect level. In addition, each storage element includes a first layer which is grown selectively on the first electrode, and a second layer which is grown selectively on the second electrode. In selected embodiments, the first layer includes a metal oxide layer selected from the group consisting of tungsten oxide (WO₃), molybdenum oxide (MoO₃), titanium selenide (TiSe₂), copper sulfide (Cu₂S. CuS), copper oxide (CuO. Cu₂O), manganese oxide (MnO₂), titanium dioxide (TiO₂), indium oxide (I₃O₄), silver sulfide (Ag₂S), and iron oxide (Fe₃O₄). In other embodiments, the second layer includes a polythiophene layer formed on top and sidewall surfaces of the second electrode, and a polypyrrole layer formed on the polythiophene layer to make direct physical contact with the first layer. Alternatively, the second layer may include a poly(3,4-ethylenedioxythiophene)-poly(styrenesulfonate) layer formed on top and sidewall surfaces of the second electrode to make direct physical contact with the first layer. The disclosed integrated circuit device may also include one or more active circuits connected through the multi-level interconnect structure which may be activated during fabrication of the integrated circuit device to selectively float or bias the first electrode to a first bias voltage while simultaneously floating or biasing the second electrode to a second bias voltage during formation of the first or second layer.

In yet another form, there is provided a method for forming a semiconductor device with a polymer memory array formed on an interconnect stack. In the disclosed methodology, a multi-level interconnect structure is formed on a semiconductor substrate. As formed in an upper interconnect level of the multi-level interconnect structure, a patterned conductive layer defines a first electrode connected to an access device, and a second electrode connected to an interconnect line and spaced apart from the first electrode by a specified memory cell width. After forming the multi-level interconnect structure, a first passive layer is selectively formed on top and sidewall surfaces of the first electrode and not the second electrode. In addition, a second active layer is selectively formed on top and sidewall surfaces of the second electrode and not the first electrode. As formed, the first passive layer is in direct physical contact with the second active layer, thereby forming a polymer memory cell. In selected embodiments, the first passive layer is selectively formed using an electrochemical deposition process to form a metal oxide layer selected from the group consisting of tungsten oxide (WO₃), molybdenum oxide (MoO₃), titanium selenide (TiSe₂), copper sulfide (Cu₂S, CuS), copper oxide (CuO, Cu₂O), manganese oxide (MnO₂), titanium dioxide (TiO₂), indium oxide (I₃O₄), silver sulfide (Ag₂S), and iron oxide (Fe₃O₄). In other embodiments, the second active layer is formed using an electrophoretical deposition process to form one or more conjugated polymer layers selected from the group consisting of poly(3,4-ethylenedioxythiophene)-poly(styrenesulfonate), polythiophene, and polypyrrole. The disclosed methodology may include activating one or more memory access circuits connected to the multi-level interconnect structure to selectively float or bias the first electrode to a first bias voltage while simultaneously floating or biasing the second electrode to a second bias voltage during selective formation of the first passive layer or second active layer.

Although the described exemplary embodiments disclosed herein are directed to various integrated circuit polymer memories and methods for making and operating same, the present invention is not necessarily limited to the example embodiments which illustrate inventive aspects of the present invention that are applicable to a wide variety of fabrication processes and/or structures. Thus, the particular embodiments disclosed above are illustrative only and should not be taken as limitations upon the present invention, as the invention may be modified and practiced in different but equivalent manners apparent to those skilled in the art having the benefit of the teachings herein. In addition, the device elements and circuits in the embodiments described above are connected to each other as shown in the figures for the sake of simplicity. In practical applications, these devices, elements circuits, etc., may be connected directly to each other or indirectly through other devices elements, circuits, etc. Thus, in an actual configuration, the elements, circuits and devices are coupled either directly or indirectly with each other. Also, the example polymer memory materials and structures may be modified or even replace with other types of memory devices formed on the upper or last metal layer. And while the memory access circuit examples described herein with reference to the row and column decoders and datapath blocks, this is merely for convenience of explanation and not intended to be limiting and persons of skill in the art will understand that the principles taught herein apply to other devices and circuits. Moreover, the thicknesses, depths, and other dimensions of the described layers and openings may deviate from the disclosed ranges or values. In addition, the terms of relative position used in the description and the claims, if any, are interchangeable under appropriate circumstances such that embodiments of the invention described herein are, for example, capable of operation in other orientations than those illustrated or otherwise described herein. The term “coupled,” as used herein, is defined as directly or indirectly connected in an electrical or non-electrical manner. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. An integrated circuit device comprising:
a semiconductor substrate comprising one or more active circuits;
a multi-level interconnect structure formed on the semiconductor substrate, the multi-level interconnect structure comprising an upper interconnect level in which a plurality of cell node electrodes and a plurality of source line electrodes are formed in an array; and
an array of polymer memory cells formed in the upper interconnect level, each polymer memory cell comprising:
a passive layer comprising at least one conductivity-facilitating compound that is formed on top and sidewall surfaces of a source line electrode, and
an active layer having an impedance state that can change that is formed on top and sidewall surfaces of an adjacent cell node electrode with sufficient thickness to make direct physical contact with the passive layer.

2. The integrated circuit device of claim 1, where the one or more active circuits comprises memory access circuitry which may be activated during fabrication of the integrated circuit device to selectively float or bias the plurality of cell node electrodes to a first bias voltage while simultaneously floating or biasing the plurality of source line electrodes to a second bias voltage during formation of the passive layer.

3. The integrated circuit device of claim 1, where the one or more active circuits comprises memory access circuitry which may be activated during fabrication of the integrated circuit device to selectively float or bias the plurality of cell node electrodes to a first bias voltage while simultaneously floating or biasing the plurality of source line electrodes to a second bias voltage during formation of the active layer.

4. The integrated circuit device of claim 1, where the multi-level interconnect structure comprises a metal-based damascene interconnect structure comprising, in each interconnect level, one or more first metal-containing interconnect features formed to be isolated by a patterned inter-layer dielectric (TLD) layer.

5. The integrated circuit device of claim 1, where the plurality of cell node electrodes and the plurality of source line electrodes are formed with copper in a last metal layer of the multi-level interconnect structure.

6. The integrated circuit device of claim 1, where passive layer comprises a metal oxide layer.

7. The integrated circuit device of claim 1, where the passive layer comprises a metal oxide layer selected from the group consisting of tungsten oxide (WO₃), molybdenum oxide (MoO₃), titanium selenide (TiSe₂), copper sulfide (Cu₂S, CuS), copper oxide (CuO, Cu₂O), manganese oxide (MnO₂), titanium dioxide (TiO₂), indium oxide (I₃O₄), silver sulfide (Ag₂S), and iron oxide (Fe₃O₄).

8. The integrated circuit device of claim 1, where the active layer comprises one or more conjugated polymer layers.

9. The integrated circuit device of claim 1, where the active layer comprises:
a polythiophene layer formed on top and sidewall surfaces of the adjacent cell node electrode, and
a polypyrrole layer formed on the polythiophene layer to make direct physical contact with the passive layer.

10. The integrated circuit device of claim 1, where the active layer comprises a poly(3,4-ethylenedioxythiophene)-poly(styrenesulfonate) layer formed on top and sidewall surfaces of the adjacent cell node electrode to make direct physical contact with the passive layer.

11. An integrated circuit device comprising:
a semiconductor substrate comprising one or more active circuits;
a multi-level interconnect structure formed on the semiconductor substrate, the multi-level interconnect structure comprising an upper interconnect level; and
a plurality of storage elements formed in an array in the upper interconnect level, each storage element comprising a first electrode and a second electrode formed in the upper interconnect level at laterally different locations,
the first electrode being connected to an access device formed in the semiconductor substrate, and
the second electrode being in contact with or forming an integral part of an interconnect line in the upper interconnect level.

12. The integrated circuit device of claim 11, wherein each storage element comprises a first layer which is grown selectively on the first electrode and a second layer which is grown selectively on the second electrode.

13. The integrated circuit device of claim 12, where the first layer comprises a metal oxide layer selected from the group consisting of tungsten oxide (WO₃), molybdenum oxide (MoO₃), titanium selenide (TiSe₂), copper sulfide (Cu₂S, CuS), copper oxide (CuO, Cu₂O), manganese oxide (MnO₂), titanium dioxide (TiO₂), indium oxide (I₃O₄), silver sulfide (Ag₂S), and iron oxide (Fe₃O₄).

14. The integrated circuit device of claim 13, where the second layer comprises:
a polythiophene layer formed on top and sidewall surfaces of the second electrode, and
a polypyrrole layer formed on the polythiophene layer to make direct physical contact with the first layer.

15. The integrated circuit device of claim 13, where the second layer comprises a poly(3,4-ethylenedioxythiophene)-poly(styrenesulfonate) layer formed on top and sidewall surfaces of the second electrode to make direct physical contact with the first layer.

16. The integrated circuit device of claim 12, further comprising one or more active circuits connected through the multi-level interconnect structure which may be activated during fabrication of the integrated circuit device to selectively float or bias the first electrode to a first bias voltage while simultaneously floating or biasing the second electrode to a second bias voltage during formation of the first or second layer.

17. A method for forming a semiconductor device, comprising:
forming a multi-level interconnect structure on a semiconductor substrate, the multi-level interconnect structure comprising a patterned conductive layer in an upper interconnect level which defines:
a first electrode connected to an access device, and
a second electrode connected to an interconnect line and spaced apart from the first electrode by a specified memory cell width;
selectively forming a first passive layer on top and sidewall surfaces of the first electrode and not the second electrode; and
selectively forming a second active layer on top and sidewall surfaces of the second electrode and not the first electrode, where the second active layer is in direct physical contact with the first passive layer to form a polymer memory cell.

18. The method of claim 17, where selectively forming the first passive layer comprises using an electrochemical deposition process to form a metal oxide layer selected from the group consisting of tungsten oxide (WO₃), molybdenum oxide (MoO₃), titanium selenide (TiSe₂), copper sulfide (Cu₂S, CuS), copper oxide (CuO, Cu₂O), manganese oxide (MnO₂), titanium dioxide (TiO₂), indium oxide (I₃O₄), silver sulfide (Ag₂S), and iron oxide (Fe₃O₄).

19. The method of claim 17, where selectively forming the second layer comprises using an electrophoretical deposition process to form one or more conjugated polymer layers selected from the group consisting of poly(3,4-ethylenedioxythiophene)-poly(styrenesulfonate), polythiophene, and polypyrrole.

20. The method of claim 17, further comprising activating one or more memory access circuits connected to the multi-level interconnect structure to selectively float or bias the first electrode to a first bias voltage while simultaneously floating or biasing the second electrode to a second bias voltage during selective formation of the first passive layer or second active layer.
